(19) United States
(12) Patent Application Publication
(10) Pub. No.: US 2014/0107295 A1
(43) Pub. Date: Apr. 17, 2014

(54) EPOXY RESIN COMPOSITION, CURED OBJECT AND OPTICAL SEMICONDUCTOR SEALING MATERIAL

(71) Applicants: Youko Hatae, Hiroshima (JP); Toshihiro Kasai, Hiroshima (JP)

(72) Inventors: Youko Hatae, Hiroshima (JP); Toshihiro Kasai, Hiroshima (JP)

(73) Assignee: MITSUBISHI RAYON CO., LTD., Tokyo (JP)

(21) Appl. No.: 14/123,141

(22) PCT Filed: May 29, 2012
(86) PCT No.: PCT/JP2012/063723

§ 371 Date: Nov. 29, 2013

(30) Foreign Application Priority Data
May 30, 2011 (JP) 2011-120703

(51) Int. Cl. H01L 23/10

(52) U.S. Cl. CPC H01L 23/10
USPC 525/107; 428/402

(57) ABSTRACT

An epoxy resin composition, a cured object thereof, and an optical semiconductor sealing material using the cured object are described. The epoxy resin composition includes an alicyclic epoxy resin (A) and a vinyl polymer particle (B). An acetone soluble part of the vinyl polymer particle (B) is 30 mass % or more. The mass average molecular weight of the acetone soluble part is 100,000 or more. The volume average primary particle diameter (Dv) is 200 nm or more. The epoxy resin composition is rapidly turned into a gel state by heating for a short time, and the transparency of the obtained cured object is good.

### BACKGROUND OF THE INVENTION

1. Technical Field

The invention relates to an epoxy resin composition, a cured object, and an optical semiconductor sealing material.

2. Description of Related Art

Epoxy resin is a material excellent in mechanical property, electrical insulation and adhesion, and has characteristics such as little shrinkage in curing. Hence, epoxy resin is extensively used in a variety of applications, such as semiconductor sealing materials, various insulating materials, adhesives and so on. In addition, among epoxy resins, those having a liquid state at normal temperature are usable for casting or coating at normal temperature and are therefore used as various paste-like materials or film forming materials.

Meanwhile, in recent years, along with high integration of circuits, demands for precise processing of liquid material, such as precise pouring or coating of liquid material using a dispenser, precise pattern coating of liquid material by screen printing, and coating of liquid material on a film with high thickness precision, have increased.

However, conventional epoxy resin compositions have high temperature dependency of viscosity so that their viscosity is remarkably reduced due to the rise in temperature until the curing. Hence, the conventional epoxy resin composition is not suitable as the above liquid material for precise processing. Especially in the field of electronic materials, because the demand for high-precision processing has increased year by year, there is an extremely strong call for an epoxy resin composition having viscosity that is not reduced even if the temperature rises or having a shape that is stabilized at an early stage.

A method of imparting the properties as described above to an epoxy resin composition has been proposed as follows. A gelation property imparting agent (hereinafter referred to as “pregel agent”), such as a specific vinyl polymer as shown in Patent Document 1, is mixed into an epoxy resin composition, so that the epoxy resin composition is rapidly turned into a gel state in heating.

In addition, in recent years, there have been notable advances in optoelectronics related technology, and high heat resistance and transparency have been required for optical semiconductor materials. In response to such requirement, in Patent Document 2, for example, it is proposed an epoxy resin composition formed by dispersing specific rubber particles in alicyclic epoxy resin to serve as a resin composition for optical semiconductor sealing that allows a cured object excellent in transparency, heat resistance and crack resistance to be obtained.

### PRIOR-ART DOCUMENTS

### Patent Documents

[Patent Document 1] International Publication No. WO2010/090246
[Patent Document 2] Japan Patent Publication No. 2010-53199

Nonetheless, though the epoxy resin composition disclosed in Patent Document 1 that has the pregel agent mixed therein shows good gelation properties, the transparency of the cured object thus obtained is not considered sufficient. Thus, the epoxy resin composition is not suitable for uses requiring high transparency, such as use in optical semiconductor materials. Moreover, while high light resistance is required for optical semiconductor materials, high light resistance is not particularly mentioned.

In addition, though the epoxy resin composition proposed in Patent Document 2 allows a cured object excellent in heat resistance and transparency to be obtained, there are cases where the viscosity of the epoxy resin composition is remarkably reduced due to rise in the temperature of the epoxy resin composition in curing, and also cases where high precision coating or pattern formation using the epoxy resin composition is hard to perform.

### SUMMARY OF THE INVENTION

The object of the invention is to provide an epoxy resin composition, a cured object thereof, and an optical semiconductor sealing material using the cured object. The epoxy resin composition is capable of being rapidly turned into a gel state by heating for a short time, and of improving transparency and light resistance of the obtained cured object.

The invention relates to the following epoxy resin composition, cured object and optical semiconductor sealing material.

(1) An epoxy resin composition including a alicyclic epoxy resin (A) and a vinyl polymer particle (B), wherein the acetone soluble part of the vinyl polymer particle (B) is 30 mass % or more, the mass average molecular weight of the acetone soluble part is 100,000 or more, and the volume average primary particle diameter (Dv) of the vinyl polymer particle (B) is 200 nm or more.

(2) The epoxy resin composition of (1), wherein the alicyclic epoxy resin (A) is at least one selected from 3,4-epoxycyclohexylmethyl 3′,4′-epoxycyclohexanecarboxylate and bisphenol A-type hydrogenated alicyclic epoxy resins.

(3) The epoxy resin composition of (1) or (2), wherein the vinyl polymer particle (B) is obtained by polymerizing a monomer material, and the monomer material includes 1 mass % or more of at least one monomer containing a functional group that is selected from a vinyl monomer containing a carboxyl group and a vinyl monomer containing a hydroxyl group.

(4) The epoxy resin composition of any one of (1) to (3), wherein the monomer material includes 3 mass % or more of the monomer containing a functional group.

(5) The epoxy resin composition of any one of (1) to (4), wherein the vinyl polymer particle (B) is a pregel agent for epoxy resin.

(6) The epoxy resin composition of any one of (1) to (5), wherein a cured object obtained by curing the epoxy resin composition and having a thickness of 3 mm has a total light transmittance of 50.0% or higher under 400 nm at 23° C.

(7) The epoxy resin composition of any one of (1) to (6), wherein the total light transmittance is 80.0% or higher.

(8) The epoxy resin composition of any one of (1) to (7), wherein the cured object obtained by curing the epoxy resin composition and having a thickness of 3 mm has a YI value of 10.0 or less after being subjected to a light resistance test under 96-hour continuous irradiation at a test temperature of 60° C. using a Dewpanel light control weather meter.

(9) A cured object obtained by curing the epoxy resin composition of any one of (1) to (8).

(10) An optical semiconductor sealing material using the epoxy resin composition of any one of (1) to (8).

(11) A pregel agent for alicyclic epoxy resin, including a vinyl polymer particle (B) with an acetone soluble part of 30 mass % or more, wherein the mass average molecular weight of the acetone soluble part is 100,000 or more, and the volume average primary particle diameter (Dv) of the vinyl polymer particle (B) is 200 nm or more.

### Effects of the Invention

The present composition enables the epoxy resin composition to be rapidly turned into a gel state by heating for a short time and allows the obtained cured object to have good transparency and light resistance, thus being suitable for various materials, such as coating materials used in the field of coating by means of dipping, casting, knife coaters, doctor coaters and so on, and sealing materials in the field of electronic materials such as highly integrated circuit and optical semiconductor, in which precise processing of liquid material, such as precise pouring or coating of liquid material using a dispenser, precise pattern coating of liquid material by screen printing, and coating of liquid material on a film with a high thickness precision, is required.

### EMBODIMENTS

### Alicyclic Epoxy Resin (A)

As the alicyclic epoxy resin (A) used in the invention, in view of imparting gelation properties to the present composition, one having an epoxy resin as described below as a main component is preferred. The epoxy resin is in a liquid state at normal temperature, or is in a solid state at normal temperature but liquefies during heating before the curing is sufficiently performed. By means of the alicyclic epoxy resin (A), the light resistance of obtained cured objects is improved.

Specific examples of the alicyclic epoxy resin include: 3,4-epoxycyclohexylmethyl 3′,4′-epoxycyclohexanecarboxylate (produced by Daicel Chemical Industries, Ltd., trade name: Celloxide 2021), adduct of ε-caprolactone dimer to 3,4-epoxycyclohexylmethyl 3′,4′-epoxycyclohexanecarboxylate (by Daicel Chemical Industries, Ltd., trade name: Celloxide 2081), 1,2,8,9-diepoxylimonene (by Daicel Chemical Industries, Ltd.; trade name: Celloxide 3000), bisphenol A-type hydrogenated alicyclic epoxy resin (by Mitsubishi Chemical Corporation, trade name: YX-8000; and by Dainippon Ink and Chemicals, Inc., trade name: EPICLON750) and so on. These may be used alone or in combination of two or more. Particularly, it is preferred to use at least one selected from 3,4-epoxycyclohexylmethyl 3′,4′-epoxycyclohexane-carboxylate and bisphenol A-type alicyclic epoxy resin as the alicyclic epoxy resin (A).

### Vinyl Polymer Particle (B)

The vinyl polymer particle (B) of the invention is obtained by polymerizing a vinyl monomer capable of radical polymerization. By means of the vinyl polymer particle (B), the obtained epoxy resin composition is imparted with gelation properties, and the light resistance of the obtained cured object is improved. Examples of the vinyl monomer capable of radical polymerization include: (meth)acrylates, such as methyl (meth)acrylate, ethyl (meth)acrylate, n-propyl (meth)acrylate, i-propyl (meth)acrylate, n-butyl (meth)acrylate, t-butyl (meth)acrylate, i-butyl (meth)acrylate, n-hexyl (meth)acrylate, n-octyl (meth)acrylate, 2-ethylhexyl (meth)acrylate, cyclohexyl (meth)acrylate, benzyl (meth)acrylate, phenyl (meth)acrylate, nonyl (meth)acrylate, decyl (meth)acrylate, dodecyl (meth)acrylate, stearyl (meth)acrylate, t-butylcyclohexyl (meth)acrylate, isobornyl (meth)acrylate, tricyclo[5.2,1.0^{2.6}]decan-8-yl methacrylate, dicyclopentadienyl (meth)acrylate, glycidyl (meth)acrylate, N,N-dimethylaminoethyl (meth)acrylate, N-methyl-2,2,6,6-tetramethylpiperidyl (meth)acrylate and so on; vinyl cyanide monomers, such as (meth)acrylonitrile and so on; aromatic vinyl monomers, such as styrene, α-methylstyrene, vinyltoluene and so on; vinyl monomers containing a hydroxyl group, such as hydroxymethyl (meth)acrylate, 2-hydroxyethyl (meth)acrylate, 2-hydroxypropyl (meth)acrylate, 2-hydroxybutyl (meth)acrylate, 4-hydroxybutyl (meth)acrylate, glycerol mono(meth)acrylate and so on; vinyl monomers containing a carboxyl group, such as acrylic acid, methacrylic acid, crotonic acid, maleic acid, itaconic acid, fumaric acid, isocrotonic acid, salicylic acid vinyloxyacetate, allyloxyacetic acid, 2-(meth)acryloyl propanoic acid, 3-(meth)acryloyl butanoic acid, 4-vinylbenzoic acid and so on; (meth)acrylamide; vinyl monomers, such as vinyl pyridine, vinyl alcohol, vinylimidazole, vinylpyrrolidone, vinyl acetate, 1-vinylimidazole and so on; itaconate esters, such as monomethyl itaconate, monoethyl itaconate, monopropyl itaconate, monobutyl itaconate, dimethyl itaconate, diethyl itaconate, dipropyl itaconate, dibutyl itaconate and so on; fumarate esters, such as monomethyl fumarate, monoethyl fumarate, monopropyl fumarate, monobutyl fumarate, dimethyl fumarate, diethyl fumarate, dipropyl fumarate, dibutyl fumarate and so on; maleate esters, such as monomethyl maleate, monoethyl maleate, monopropyl maleate, monobutyl maleate, dimethyl maleate, diethyl maleate, dipropyl maleate, dibutyl maleate and so on. These may be used alone or in combination of two or more. Among these, in view of easy radical polymerization and easy emulsion polymerization, (meth)acrylates are preferred. Moreover, in view of suppressing thermal decomposition of the vinyl polymer particle (B), acrylates are preferably contained. In addition, in the invention, “(meth)acry-” means “acry-” or “methacry-.”

In the invention, the vinyl polymer particle (B) is preferably obtained by polymerizing a monomer material. The monomer material includes 1 mass % or more of at least one monomer containing a functional group that is selected from a vinyl monomer containing a carboxyl group and a vinyl monomer containing a hydroxyl group. By doing so, the transparency of the cured object obtained by curing the present composition becomes excellent.

In view of the transparency of the present cured object, the content of the at least one monomer containing a functional group and selected from a vinyl monomer containing a carboxyl group and a vinyl monomer containing a hydroxyl group in the monomer material is preferably not less than 3 mass %, more preferably not less than 4 mass %, and particularly preferably not less than 6 mass %. In addition, the content is preferably not more than 40 mass %.

In view of easy radical polymerization and easy emulsion polymerization, the vinyl monomer containing a carboxyl group is preferably methacrylic acid.

In view of easy radical polymerization and easy emulsion polymerization, the vinyl monomer containing a hydroxyl group is preferably 2-hydroxyethyl methacrylate.

In the invention, when multistage (two or more stages) polymerization is implemented in order to obtain the vinyl polymer particle (B), as the monomer material in each stage, it is preferred to use a monomer that includes 1 mass % or more of at least one monomer containing a functional group that is selected from at least one of a vinyl monomer containing a carboxyl group and a vinyl monomer containing a hydroxyl group. Moreover, the compositions of the monomer material in the respective stages of the multistage polymerization may be the same or different.

The vinyl polymer particle (B) used in the invention has an acetone soluble part of 30 mass % or more, wherein the mass average molecular weight of the acetone soluble part is 100,000 or more, and the volume average primary particle diameter of the particle is 200 nm or more. The vinyl polymer particle (B) functions as a pregel agent for the alicyclic epoxy resin (A). The so-called “pregel agent” refers to a component that imparts gelation properties by being mixed in a liquid resin having fluidity, such as an epoxy resin. A resin composition having the pregel agent mixed therein is rapidly turned into a gel state when, for example, being heated.

By setting the content of the acetone soluble part in the vinyl polymer particle (B) to 30 mass % or more, sufficient gelation properties are imparted to the present composition. Even at a high temperature, flow of the epoxy resin is suppressed. In addition, by setting the content of the acetone soluble part in the vinyl polymer particle (B) to 40 mass % or more, preferably 50 mass % or more and more preferably 80 mass % or more, there is a tendency that not only the present composition is imparted with sufficient gelation properties, but also the present cured object can be provided with better transparency. The acetone soluble part is properly configured by adjusting the content of a cross-linkable monomer in the monomer material.

The acetone soluble part in the vinyl polymer particle (B) refers to a value obtained by the following measurement method.

A solution formed by dissolving 1 g of vinyl polymer particles in 50 g of acetone is refluxed at 70° C. for 6 hours, followed by centrifugal separation for 30 min at 14,000 rpm at 4° C. using a centrifugal separator (“CRG SERIES” made by Hitachi, Ltd.). The separated acetone soluble part is removed by decantation, so as to obtain an acetone insoluble part. The obtained acetone insoluble part is dried at 50° C. for 24 hours using a vacuum dryer, and then the mass thereof is measured. The acetone soluble part (%) in the vinyl polymer particle is calculated by the following formula.

(acetone soluble part)=(1−mass of acetone insoluble part)×100

Particularly, in applications in which the present composition is used in a low viscosity state, high gelation properties are required to be imparted by a small amount of addition. Thus, the more the acetone soluble part in the vinyl polymer particle (B), the wider the applicable range of the vinyl polymer particle (B).

By setting the mass average molecular weight of the acetone soluble part in the vinyl polymer particle (B) to 100,000 or more, preferably 400,000, more preferably 600,000 or more and particularly preferably 750,000 or more, high gelation properties is imparted by a small amount of addition. Even at a high temperature, flow of the epoxy resin is suppressed. In addition, in view of suppressing decrease in solubility of the epoxy resin and of turning the epoxy resin into a sufficient gel state in a short time, the mass average molecular weight of the acetone soluble part in the vinyl polymer particle (B) is preferably 20,000,000 or less, more preferably 10,000,000 or less, and further preferably 5,000,000 or less.

The mass average molecular weight of the acetone soluble part in the vinyl polymer particle (B) refers to a value obtained by the following method.

Acetone is distilled away from the acetone soluble part obtained from the measurement of the acetone soluble part, thereby obtaining solid matter of the acetone soluble part. With respect to the solid matter, the mass average molecular weight is measured using gel permeation chromatography under the following conditions.

Apparatus: HLC8220 made by Tosoh Corporation

Column: TSKgel Super HZM-M (inner diameter 4.6 mm×length 15 cm) made by Tosoh Corporation; number of columns: 4; exclusion limit: 4×10⁶

Temperature: 40° C.

Carrier solution: tetrahydrofuran

Flow rate: 0.35 ml/min

Sample concentration: 0.1%

Sample injection amount: 10 μl

Standard: polystyrene

In the invention, the gelation properties are evaluated with gelation temperature and gelation performance obtained by a later-described measurement method.

By setting the volume average primary particle diameter of the vinyl polymer particle (B) to 200 nm or more and more preferably 500 nm or more, the total surface area of the vinyl polymer particle (B) is sufficiently reduced, thus suppressing high viscosity of the present composition. In addition, in view of possibility of achieving a fine pitch or thinning of the present cured object, the volume average primary particle diameter of the vinyl polymer particle (B) is preferably not more than 8 μm, more preferably not more than 5 μm, and further preferably not more than 1 μm. A particle having a volume average primary particle diameter of 200 nm or more can be obtained by emulsion polymerization, etc. A particle having a volume average primary particle diameter of ≧500 nm is obtained by the following method, etc. The method includes emulsion-polymerizing a monomer mixture to form a seed particle while no emulsifier is used at an early stage of the polymerization, and then performing polymerization by dropping a monomer mixture containing an emulsifier to grow the seed particle.

In addition, the vinyl polymer particle (B) is obtained as an aggregation powder formed by a large number of primary particles. However, by setting the volume average primary particle diameter of the vinyl polymer particle (B) to 200 nm or more, the aggregation powder is easily dispersed into primary particles, and the dispersibility of the vinyl polymer particle (B) in the alicyclic epoxy resin (A) becomes good.

In the invention, the monodispersity (Dv/Dn) represented by the ratio of the volume average primary particle diameter (Dv) to the number average primary particle diameter (Dn) of the vinyl polymer particle (B) is preferably not more than 3.0, more preferably not more than 2.0, and particularly preferably not more than 1.5. As the monodispersity of the vinyl polymer particle (B) is higher (Dv/Dn is closer to 1), there is a tendency that gelation of the present composition proceeds rapidly in a shorter time and storage stability of the present composition easily coexists.

In the invention, the content of alkali metal ions in the vinyl polymer particle (B) is preferably not more than 10 ppm, more preferably not more than 5 ppm, and particularly preferably not more than 1 ppm. By setting the content of alkali metal ions in the vinyl polymer particle (B) in the above range, there is a tendency that the present composition is widely applicable to uses requiring high electrical properties, such as semiconductor wafers, thin electronic apparatuses and so on, i.e., uses requiring prevention of insulation failure due to presence of a small amount of ionic impurities.

Moreover, in the invention, the content of alkali metal ions in the vinyl polymer particle (B) is the total amount of Na ions and K ions, and refers to a value obtained by the later-described method of measuring the content of alkali metal ions.

In the invention, the content of sulfate ions (SO₄²⁻) in the vinyl polymer particle (B) is preferably 20 ppm or less. By setting the content of sulfate ions (SO₄²⁻) in the vinyl polymer particle (B) in this range, there is a tendency that when the present composition is used in an environment in contact with wires made of metal such as copper or aluminum or circuit wiring, conduction failure or malfunction due to metal corrosion caused by remaining SO₄²⁻ in the vinyl polymer particle (B) is prevented.

Accordingly, in polymerization of the vinyl polymer particle (B), an emulsifier or dispersion stabilizer not containing sulfonic acid ion, sulfinic acid ion or sulfate ester ion is preferably used.

As the shape of the vinyl polymer particle (B), in view of suppressing high viscosity of the present composition to obtain the present composition having good fluidity, a spherical shape is preferable.

In the invention, in order for the vinyl polymer particles (B) to exhibit the intended gelation properties, a plurality of the vinyl polymer particles (B) having different gelation temperatures may be used in combination.

As the polymerization method for obtaining the vinyl polymer particle (B), in view of easily obtaining the particle in a spherical shape and easily controlling particle morphology, an emulsion polymerization method, a soap-free emulsion polymerization method, a swelling polymerization method, a mini-emulsion polymerization method, a dispersion polymerization method and a fine suspension polymerization method are preferred. Among these, in view of easily obtaining a polymer being excellent in dispersibility and having a particle diameter also capable of achieving a fine pitch, a soap-free emulsion polymerization method is more preferable.

In addition, the internal morphology of the primary particle of the vinyl polymer particle (B) is not particularly limited, and is, for example, a unitary structure, a core-shell structure or a gradient structure.

The method of controlling the internal morphology of the primary particle of the vinyl polymer particle (B) is, for example, making the primary particle of the vinyl polymer particle (B) a multi-structured particle and controlling the inner side and outer side of the particle to have different solubility parameters or molecular weights. The method is preferable in view of easily realizing coexistence of two properties including the storage stability (pot life) and gelation rate of the composition.

The method for controlling the internal morphology of the primary particle of the vinyl polymer particle (B) and having high industrial utility is, for example, a method of polymerization by sequentially dropping monomer materials of different composition in a multi-step manner.

In the invention, the method of confirming that the primary particle of the vinyl polymer particle (B) has a core-shell structure is, for example, confirming that both of the following requirements are met: that a particle diameter of a polymer particle sampled during the polymerization is definitely growing, and that the minimum film-forming temperature (MFT) of the polymer particle sampled during the polymerization or the solubility of the same in various solvents is varying.

In addition, another method of confirming that the primary particle of the vinyl polymer particle (B) has a core-shell structure is, for example, observing a section of the vinyl polymer particle (B) recovered as an aggregate by a transmission electron microscope (TEM) to confirm if there is any structure in a concentric circular shape, or observing a section of the vinyl polymer particle (B) recovered as a freeze-fractured aggregate by a cryo-scanning electron microscope (Cryo-SEM) to confirm if there is any structure in a concentric circular shape.

In the invention, in polymerizing the monomer material to obtain the vinyl polymer particle (B), polymerization materials such as a polymerization initiator, an emulsifier, a dispersion stabilizer, a chain-transfer agent and so on may be included.

Examples of the polymerization initiator include: persulfate salts, such as potassium persulfate, sodium persulfate, ammonium persulfate and so on; oil-soluble azo compounds, such as azobisisobutyronitrile, 2,2′-azobis(2-methylbutyronitrile), 2,2′-azobis(2,4-dimethylvaleronitrile), 2,2′-azobis(4-methoxy-2,4-dimethylvaleronitrile), 1-1′-azobis(cyclohexane-1-carbonitrile), dimethyl-2,2′-azobis(2-methylpropionate) and so on; water-soluble azo compounds, such as 4,4′-azobis(4-cyanovaleric acid), 2,2′-azobis{2-methyl-N-[1,1-bis(hydroxymethyl)-2-hydroxyethyl]propionamide}, 2,2′-azobis{2-methyl-N-[2-(2-hydroxyethyl]propionamide}, 2,2′-azobis{2-methyl-N-[2-(1-hydroxybutyl)]propionamide}, 2,2′-azobis[2-(5-methyl-2-imidazolin-2-yl)propane] and salts thereof, 2,2′-azobis[2-(2-imidazolin-2-yl)propane] and salts thereof, 2,2′-azobis[(2-(3,4,5,6-tetrahydropyrimidin-2-yl)propane] and salts thereof, 2,2′-azobis[2-[1-(2-hydroxyethyl)-2-imidazolin-2-yl]propane] and salts thereof, 2,2′-azobis(2-methylpropionamidine) and salts thereof, 2,2′-azobis(2-methylpropyneamidine) and salts thereof, 2,2′-azobis[N-(2-carboxyethyl)-2-methylpropionamidine] and salts thereof, and so on; and organic peroxides, such as benzoyl peroxide, cumene hydroperoxide, t-butylhydroperoxide, t-butylperoxy-2-ethylhexanoate, t-butylperoxyisobutyrate, lauroyl peroxide, propylbenzene hydroperoxide, p-mentha-hydroperoxide, 1,1,3,3-tetramethylbutyl peroxy-2-ethylhexanoate and so on. These may be used alone or in combination of two or more. Among them, the polymerization initiators not containing alkali metal ions are preferred, and ammonium persulfate and azo compounds are more preferred. In addition, in view of reducing the content of sulfate ions (SO₄²⁻) in the vinyl polymer particle (B), it is more preferred to use an azo compound not containing chloride ions and ammonium persulfate in combination.

In addition, in the invention, as the polymerization initiator, within a scope not deviating from the purpose, a redox-type initiator, which is formed by combining a reducing agent, such as sodium formaldehydesulfoxylate, L-ascorbic acid, fructose, dextrose, sorbose or inositol etc., with ferrous sulfate, ethylenediaminetetraacetic acid disodium salt and peroxide, may be used.

Exemplary emulsifiers are anionic emulsifiers, cationic emulsifiers, nonionic emulsifiers, Betaine-type emulsifiers, polymeric emulsifiers and reactive emulsifiers.

Examples of the anionic emulsifiers include: alkylsulfonate salts, such as sodium alkylsulfonate and so on; alkyl sulfate salts, such as sodium lauryl sulfate, ammonium lauryl sulfate, triethanolamine lauryl sulfate and so on; alkyl phosphate salts, such as potassium polyoxyethylene alkylphosphate and so on; alkylbenzene sulfonate salts, such as sodium alkylbenzene sulfonate, sodium dodecylbenzenesulfonate, sodium alkylnaphthalenesulfonate and so on; and dialkyl sulfosuccinate salts, such as sodium dialkyl sulfosuccinate, ammonium dialkyl sulfosuccinate and so on.

Examples of the cationic emulsifiers include: alkyl amine salts, such as stearylamine acetate, coconut amine acetate, tetradecylamine acetate, octadecylamine acetate and so on; and quaternary ammonium salts, such as lauryltrimethylammonium chloride, stearyl trimethylammonium chloride, cetyltrimethylammonium chloride, distearyldimethylammonium chloride, and alkylbenzylmethylammonium chloride, etc.

Examples of the non-ionic emulsifiers include: sorbitan fatty acid esters, such as sorbitan monolaurate, sorbitan monopalmitate, sorbitan monostearate, sorbitan tristearate, sorbitan monooleate, sorbitan trioleate, sorbitan monocaprylate, sorbitan monomyristate, sorbitan monobehenate and so on; polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan tristearate, polyoxyethylene sorbitan monooleate, polyoxyethylene sorbitan triisostearate and so on; polyoxyethylene sorbitol fatty acid esters, such as polyoxyethylene sorbitol tetraoleate and so on; polyoxyethylene alkyl ethers, such as polyoxyethylene lauryl ether, polyoxyethylene cetyl ether, polyoxyethylene stearyl ether, polyoxyethylene oleyl ether, polyoxyethylene myristyl ether and so on; polyoxyethylene alkyl esters, such as polyoxyethylene monolaurate, polyoxyethylene monostearate, polyoxyethylene monooleate and so on; and polyoxyalkylene derivatives, such as polyoxyethylene alkylene alkylether, polyoxyethylene distyrenated phenyl ether, polyoxyethylene tribenzylphenylether, polyoxyethylene polyoxypropylene glycol, etc.

Example of Betaine-type emulsifiers are: alkyl Betaine, such as lauryl betaine and stearyl betaine, etc; and alkylamine oxide, such as lauryl dimethylamine oxide etc.

Example of the polymeric emulsifiers include: sodium polycarboxylate, ammonium polycarboxylate, polycarboxylic acid and so on.

Examples of the reactive emulsifiers include: polyoxyalkylene alkenyl ethers, such as polyoxyalkylene alkenyl ether ammonium sulfate and so on.

These emulsifiers may be used alone or in combination of two or more. Among them, the emulsifiers not containing alkali metal ions are preferred, and dialkyl sulfosuccinate and polyoxyalkylene derivatives are more preferred. In addition, in view of decreasing the amount of the sulfonic acid compound and so on, it is more preferred to use dialkyl sulfosuccinate and polyoxyalkylene derivatives in combination.

Examples of the dispersion stabilizer include: poorly water-soluble inorganic salts, such as calcium phosphate, calcium carbonate, aluminum hydroxide, starch silica and so on; non-ionic polymeric compounds, such as polyvinyl alcohol, polyethylene oxide, cellulose derivatives and so on; and anionic polymeric compounds, such as polyacrylic acid and salts thereof, polymethacrylic acid and salts thereof, copolymers of methacrylate and methacrylic acid or salt thereof, and so on. These may be used alone or in combination of two or more. Among them, in view of excellent electrical properties, non-ionic polymeric compounds are preferred.

Examples of the chain-transfer agent include: mercaptans, such as n-dodecyl mercaptan, t-dodecyl mercaptan, n-octyl mercaptan, t-octyl mercaptan, n-tetradecyl mercaptan, n-hexyl mercaptan, n-butyl mercaptan and so on; halogen compounds, such as carbon tetrachloride, ethylene bromide and so on; and α-methyl styrene dimer. These may be used alone or in combination of two or more.

The method of recovering the vinyl polymer particle (B) is, for example, in cases where the vinyl polymer particle (B) is obtained by suspension polymerization, filtering, washing with water, and drying the microparticle dispersion liquid obtained by the suspension polymerization.

In addition, in cases where the vinyl polymer particle (B) is obtained through emulsion polymerization, the method of recovering the vinyl polymer particle (B) is, for example, a wet coagulation method in which an electrolyte is added to the latex obtained by emulsion polymerization to aggregate the latex and the obtained aggregate is washed with water and dried to be recovered as a powder of the vinyl polymer particle (B), or a drying method in which the vinyl polymer particle (B) is powdered for recovery by removing water using a drying apparatus such as a spray dryer.

In the invention, as the method of recovering the vinyl polymer particle (B), the recovery method using a spray dryer achieves good dispersibility when being mixed in the alicyclic epoxy resin (A) due to less thermal history, so that the dispersion in the alicyclic epoxy resin (A) is in the form of the primary particle of the vinyl polymer particle (B). Hence, such recovery method is advantageous in uses requiring optical properties such as transparency and so on, such as optical semiconductor materials.

The spray-drying method is a method in which the latex of the vinyl polymer particle (B) is sprayed in the form of micro droplets and is dried while being blown with a hot wind. In the spray-drying method, the method of generating droplets is, for example: a rotating disk method, a pressure nozzle method, a two-fluid nozzle method, and a pressurized two-fluid nozzle method. The capacity of the dryer may be any capacity from small scale as used in a laboratory to large scale as used industrially.

The location of the inlet portion that is a feeding section of heated gas for drying, and the location of the outlet portion that is an exhaust port of the heated gas for drying and the powder are set to have the same conditions as those of usually used spray-drying apparatuses. As the spray drying is performed, the latex of the vinyl polymer particle (B) may be used alone, or a mixture of a plurality of kinds of latex may be used.

In the invention, in order to improve powder properties such as blocking in spray drying, bulk specific gravity and so on, the spray drying may be performed on a latex of the vinyl polymer particle (B) added with an inorganic filler such as silica, talc or calcium carbonate, etc., an additive such as polyacrylate, polyvinyl alcohol or polyacrylamide, etc., or an antioxidant, etc.

Present Composition

The present composition is a composition including the alicyclic epoxy resin (A) and the vinyl polymer particle (B).

The amount of the vinyl polymer particle (B) mixed in the present composition is preferably 1 mass part or more, and more preferably 3 mass parts or more, relative to 100 mass parts of the alicyclic epoxy resin (A). By setting the amount of the mixed vinyl polymer particle (B) to 1 mass part or more, there is a tendency that the present composition is obtained having excellent gelation properties, and exudation or pattern disturbance, etc., of the present composition occurring in making various materials using the present composition is suppressed.

In addition, the amount of the vinyl polymer particle (B) mixed in the present composition is preferably 50 mass parts or less, and more preferably 30 mass parts or less, relative to 100 mass parts of the alicyclic epoxy resin (A). By setting the amount of the mixed vinyl polymer particle (B) to 50 mass parts or less, there is a tendency that high viscosity of the present composition is suppressed and workability or operability in manufacture of various materials using the present composition is improved.

A cured object obtained by curing the present composition to have a thickness of 3 mm has a total light transmittance of preferably 50% or higher, and more preferably 80.0% or higher. Herein, the total light transmittance refers to a value obtained by the later-described measurement method. By making the total light transmittance in this range, the object is also applicable to uses requiring high transparency, such as optical semiconductor materials and so on. In order to make the total light transmittance 50% or higher, adjustment is made by means of the vinyl polymer particle (B) that has an acetone soluble part of 30 mass % or more and is obtained by polymerizing a monomer material that includes 1 mass % or more of at least one monomer containing a functional group that is selected from a vinyl monomer containing a carboxyl group and a vinyl monomer containing a hydroxyl group.

<Total Light Transmittance>

To the above epoxy resin composition, 77 mass parts of 4-methylhexahydrophthalic anhydride (produced by New Japan Chemical Co., Ltd., trade name: “Rikacid MH-700”) as a curing agent for epoxy resin, and 1 mass part of tetrabutylphosphonium diethylphosphodithionate (by Nippon Chemical Industrial Co., Ltd., trade name: “Hishicolin PX-4ET”) as a curing accelerator are added. The resultant is again mixed and defoamed for 2 minutes at a rotation speed of 1,200 rpm under a reduced pressure of 3 KPa using a planetary vacuum mixer (made by THINKY, trade name: “Awatori Rentaro ARV-310LED”), thereby obtaining an epoxy resin composition containing a curing agent and a curing accelerator.

A mold is made by two tempered glass plates having a length of 300 mm, a width of 300 mm and a thickness of 5 mm, wherein a polyethylene terephthalate (PET) film (by Toyobo Co., Ltd., trade name: TN200) is attached to a surface of each of the plates, the tempered glass plates are disposed opposite with the surfaces having the PET films thereon face-to-face, and a Teflon (registered trademark) spacer sheet having a thickness of 3 mm is sandwiched between the tempered glass plates.

Next, the above epoxy resin composition containing a curing agent and a curing accelerator flows into the mold and is fixed by a holder, followed by being pre-cured at 100° C. for 3 hours, then cured at 120° C. for 4 hours, and then removed from the mold to form a cured object having a thickness of 3 mm.

A test piece having a length of 30 mm, a width of 30 mm and a thickness of 3 mm is cut from the obtained cured object, and evaluation on the haze, transmittance and light resistance thereof is performed.

In addition, it is preferred that the cured object obtained by curing the present composition to have a thickness of 3 mm has a YI value of 10.0 or less after being subjected to a light resistance test under 96-hour continuous irradiation at a test temperature of 60° C. using a Dewpanel light control weather meter. In the invention, the YI value after a weather resistance test refers to a value with respect to the test piece used in the above measurement of total light transmittance that is obtained by the later-described weather resistance test method and measurement method for YI. Within this range, the present composition is also applicable to uses requiring high light resistance, such as optical semiconductor materials, etc. To make the YI 10.0 or less, adjustment is made by means of the alicyclic epoxy resin (A) and the vinyl polymer particle (B).

Various additives may be mixed in the present composition within a range not impairing the effects of the invention.

Examples of the additive include: conductive fillers such as silver powder, gold powder, nickel powder, copper powder and so on; insulating fillers such as aluminum nitride, calcium carbonate, silica, alumina and so on; thixotropy imparting agents, flow improvers, flame retardants, thermostabilizers, antioxidants, ultraviolet absorbers, ion adsorbing bodies, coupling agents, release agents and stress relaxing agents.

The flame retardant, if within a scope not deviating from the object of the invention, is exemplified by well-known flame retardants such as phosphorus flame retardants, halogen-based flame retardants, inorganic flame retardants and so on.

Example of the thermostabilizer include: phenol-type antioxidants, sulfur-based antioxidants and phosphorus antioxidants. Each of the antioxidants may be used alone. Nevertheless, it is preferred that two or more thereof are used in combination, such as phenol-type and sulfur-based ones, or phenol-type and phosphorus ones.

A well-known mixing apparatus may be used to prepare the present composition. The mixing apparatus is, for example: a Raikai mixer, an attritor, a planetary mixer, a dissolver, a three-roll, a ball mill and a bead mill. These may be used alone or in combination of two or more.

When the additive and so on are mixed in the present composition, the order of mixing is not particularly limited. However, in order to sufficiently exhibit the effects of the invention, the mixing of the vinyl polymer particle (B) is preferably performed as late as possible. In addition, in cases such as a case where a temperature in the system rises due to shear heating resulting from the mixing, it is preferred to make an effort to prevent the temperature from rising during the mixing.

The present composition is applicable to a variety of applications, such as, liquid sealing materials, such as underfilling materials for primary mounting, underfilling materials for secondary mounting, glob top materials in wire bonding and so on; sealing sheets for collective sealing of various chips on a substrate; pre-dispensing type underfilling materials; sealing sheets for collective sealing at a wafer level; adhesion layers for three-layered copper clad laminate; adhesion layers such as die bond films, die attach films, interlayer insulating films and cover-lay films; adhesive pastes such as die bond pastes, interlayer insulating pastes, conductive pastes and anisotropic conductive pastes; sealing materials of light-emitting diode; optical adhesives; and sealing materials of various flat panel displays such as liquid crystal and organic electroluminescence (EL) displays.

Present Cured Object

The present cured object is obtained by curing the present composition.

Curing conditions of the present composition for obtaining the present cured object are properly determined according to the types, the contents and so on of the components of the present composition. However, the curing temperature is usually 80° C. to 180° C.

A curing agent is used when curing the present composition. Examples of the curing agent include: anhydride, amine compounds and phenol compounds.

Examples of the anhydride are: phthalic anhydride, methyl tetrahydrophthalic anhydride, methyl hexahydrophthalic anhydride, hexahydrophthalic anhydride, tetrahydrophthalic anhydride, trialkyl tetrahydrophthalic anhydride, methyl himic anhydride, methylcyclohexene tetracarboxylic anhydride, trimellitic anhydride, pyromellitic dianhydride, benzophenone tetracarboxylic anhydride, ethyleneglycol bistrimellitate, glycerol tristrimellitate, dodecenyl succinic anhydride, polyazelaic polyanhydride, and poly(ethyloctadecanedioic acid) anhydride. These may be used alone or in combination of two or more. Among them, methyl hexahydrophthalic anhydride and hexahydrophthalic anhydride are preferred for uses requiring weather resistance, light resistance, heat resistance and so on.

Examples of the amine compound include: aliphatic polyamines, such as ethylenediamine, diethylenetriamine, triethylenetetramine, tetraethylenepentamine, hexamethylene diamine, trimethyl hexamethylene diamine, m-xylenediamine, 2-methyl pentamethylenediamine, diethylaminopropyl amine and so on; alicyclic polyamines, such as isophorone diamine, 1,3-bisaminomethylcyclohexane, methylene biscyclohexanamine, norbornenediamine, 1,2-diaminocyclohexane, bis(4-amino-3-methyldicyclohexyl)methane, diaminodicyclohexylmethane, 2,5(2,6)-bis(aminomethyl)bicyclo[2,2,1]heptane and so on; and aromatic polyamines, such as diaminodiethyldiphenylmethane, diaminophenylmethane, diaminodiphenylsulphone, diaminodiphenyl methane, m-phenylenediamine, diaminodiethyltoluene and so on. These may be used alone or in combination of two or more. For uses requiring weather resistance, light resistance and heat resistance etc., 2,5(2,6)-bis(aminomethyl)bicyclo[2,2,1]heptane and isophorone diamine are preferred.

Examples of the phenol compound include: phenolic novolac resin, creosol novolac resin, bisphenol A, bisphenol F, bisphenol AD, and diallyl derivatives of these bisphenols. These may be used alone or in combination of two or more. Among them, in view of the curing ability of the present composition and mechanical strength of the present cured object, bisphenol A is preferred.

When used as sealing resin for optical semiconductor material, the curing agent preferably has relatively less coloration. For example, an anhydride-type curing agent is preferably used, and an alicyclic anhydride-type curing agent is more preferred.

Examples of the alicyclic anhydride-type curing agent are: hexahydrophthalic anhydride, methylhexahydrophthalic anhydride, tetrahydrophthalic anhydride and hydrogenated methylnadic anhydride. These may be used alone or in combination of two or more.

In view of the heat resistance and curing ability of the present cured object, the amount of the curing agent used is preferably 50 to 150 mass parts, and more preferably 60 to 140 mass parts, relative to 100 mass parts of the alicyclic epoxy resin (A). More specifically, in the case of anhydride, the amount of anhydride group relative to 1 equivalent of epoxy group is preferably 0.7 to 1.3 equivalents and more preferably 0.8 to 1.1 equivalents. In addition, in the case of amine compounds, the amount of active hydrogen relative to 1 equivalent of epoxy group is preferably 0.3 to 1.4 equivalents and more preferably 0.4 to 1.2 equivalents. Moreover, in the case of phenol compounds, the amount of active hydrogen relative to 1 equivalent of epoxy group is preferably 0.3 to 0.7 equivalent and more preferably 0.4 to 0.6 equivalent.

Within a scope not impairing the transparency of the present cured object, a curing accelerator may be used in the curing of the present composition. The curing accelerator has a function of accelerating the reaction between the alicyclic epoxy resin (A) and the curing agent. When the present composition is used as sealing resin, a curing accelerator causing the present cured object to have less coloration is preferred.

Examples of the curing accelerator include: organophosphine-type curing accelerators such as triphenylphosphine, diphenylphosphine and so on; imidazole-type curing accelerators such as 2-methylimidazole, 2-phenyl-4-methylimidazole, 2-phenylimidazole and so on; tertiary amine-type curing accelerators such as 1,8-diazabicyclo(5,4,0)undec-7-ene, triethanolamine, benzylmethylamine and so on; and tetraphenyl borate-type curing accelerators such as tetraphenylphosphonium tetraphenylborate, etc. These may be used alone or in combination of two or more.

The mixing proportion of the curing accelerator is preferably 0.05 to 5 mass parts relative to 100 mass parts of the alicyclic epoxy resin (A).

The present composition is particularly useful as an optical semiconductor sealing material. For example, there is mentioned a method of filling the present composition in optical semiconductor and then curing it for use as a sealant.

Examples of the optical semiconductor include: optical semiconductor electronic components such as photodiodes and phototransistors, etc.; and electronic components such as integrated circuits (IC), large-scale IC, transistors, thyristors, diodes and so on.

### EMBODIMENTS

The invention is specifically described below with examples. In addition, in the examples and comparative examples, evaluation was performed with respect to the particle diameter and monodispersity of the vinyl polymer particle in vinyl polymer latex, the mass average molecular weight (Mw) and number average molecular weight (Mn) of the polymer in the acetone soluble part, the content of alkali metal ions in the vinyl polymer particle, the dispersibility of the vinyl polymer particle in the epoxy resin composition, the gelation temperature and gelation performance as the gelation properties of the epoxy resin composition, as well as the haze, transmittance and light resistance of the cured object of the epoxy resin composition.

(1) Particle Diameter and Mono-Dispersity

The vinyl polymer latex was diluted with ion-exchanged water, and then the Dv and Dn of the vinyl polymer particle were measured using a laser diffraction/scattering particle diameter distribution measurement apparatus (made by Shimadzu Corporation, “SALD-7100”), thereby obtaining Dv/Dn.

In the above measurement, the refractive index calculated from the monomer composition for obtaining the vinyl polymer was taken as the refractive index of the vinyl polymer particle. In addition, when the vinyl polymer particle was a multistructured polymer having a core-shell structure or the like, the refractive index of the polymer in each layer was calculated. The average refractive index of a whole vinyl polymer particle was calculated from the mass ratio of each layer, and was taken as the refractive index of the vinyl polymer particle.

The above particle diameter is taken as a median diameter. In addition, the sample concentration of the vinyl polymer latex was properly adjusted to be in a proper range in a scattered light intensity monitor attached to the apparatus.

(2) Acetone Soluble Part

A solution formed by dissolving 1 g of the vinyl polymer particles in 50 g of acetone was refluxed at 70° C. for 6 hours, followed by centrifugal separation at 14,000 rpm at 4° C. for 30 min by means of a centrifugal separator (“CRG SERIES” made by Hitachi, Ltd.). By removing the separated acetone soluble part through decantation, an acetone insoluble part was obtained.

The obtained acetone insoluble part was dried at 50° C. for 24 hours by a vacuum dryer, the mass thereof was measured, and then the acetone soluble part (%) in the vinyl polymer particle was calculated with the following formula:

(acetone soluble part)=(1−mass of acetone insoluble part)×100.

(3) Molecular Weight of Acetone Soluble Part

Acetone was distilled away from the acetone soluble part obtained in the above measurement of the acetone soluble part, thereby obtaining solid matter of the acetone soluble part. For the solid matter, Mw was measured by GPC under the following conditions. In addition, the Mn was also measured.

Apparatus: HLC8220 made by Tosoh Corporation

Column: TSKgel Super HZM-M (inner diameter 4.6 mm×length 15 cm) made by Tosoh Corporation; number of columns: 4; exclusion limit: 4×10⁶

Temperature: 40° C.

Carrier solution: tetrahydrofuran

Flow rate: 0.35 ml/min

Sample concentration: 0.1%

Sample injection amount: 10 μl

Standard: polystyrene

(4) Content of Alkali Metal Ions

An amount of 20 g of the vinyl polymer particles were taken into a glass pressure resistant container, and 200 ml of ion-exchanged water was added thereto using a measuring cylinder. After being covered with a lid, the resultant was strongly shaken to be dispersed uniformly, thereby obtaining a dispersion liquid of the vinyl polymer. After that, the obtained dispersion liquid was left at rest in a Geer oven at 95° C. for 20 hours to extract the ion components in the vinyl polymer particle.

Next, the glass container was removed from the oven and cooled. Then the dispersion liquid was filtered using a membrane filter (produced by Advantec Toyo Kaisha, Ltd., model no.: A020A025A) made of 0.2 μm of cellulose-mixed ester. 100 ml of the filtered liquid was used to measure the content of alkali metal ions in the vinyl polymer particle. Moreover, the content of alkali metal ions refers to the total amount of Na ions and K ions.

Inductively coupled plasma (ICP) emission spectrometer: IRIS “Intrepid II XSP” made by Thermo Electron Corporation.

Quantitative method: absolute calibration curve method by use of concentration—known samples (4 points of 0 ppm, 0.1 ppm, 1 ppm and 10 Ppm)

Measurement wavelength: 589.5 nm (Na ion) and 766.4 nm (K ion)

(5) Dispersibility The state of dispersion of the vinyl polymer particle in an epoxy resin composition was measured using a grind gauge according to JIS K-5600, and the dispersibility of the vinyl polymer particle in the epoxy resin composition was evaluated as follows:

◯: 5 μm or less;

x: more than 5 μm.

(6) Gelation Temperature

For the epoxy resin composition, the temperature dependence of its viscoelasticity was measured by a dynamic viscoelasticity measurement apparatus (“Rheosol G-3000” made by UBM, parallel plate diameter: 40 mm, gap: 0.4 mm, frequency: 1 Hz, twist angle: 1 degree) under the conditions of a starting temperature of 40° C., an ending temperature of 200° C. and a rate of temperature rise of 4° C./min.

Moreover, when the temperature of an epoxy resin composition that has a ratio (G″/G′=tan δ) of storage elastic modulus G′ to loss elastic modulus G″ of more than 20 at a starting point of measurement was being increased, once the above ratio became 20 or less, it was determined that gelation had occurred, and the temperature at which tan δ=20 was defined as the gelation temperature.

(7) Gelation Performance

In the above measurement of gelation temperature of the epoxy resin composition, the storage elastic modulus G′ at the temperature lower than the gelation temperature by 20° C. was designated G′_{A}, and the storage elastic modulus G′ at the temperature higher than the gelation temperature by 20° C. was designated G′_{B} (arrival elastic modulus), and the ratio thereof (G′_{B}/G′_{A}) was obtained to evaluate the gelation performance based on the following standard.

◯: G′_{B}/G′_{A} is 1,000 or more.

Δ: G′_{B}/G′_{A} is less than 1,000.

Moreover, a value of G′_{B}/G′_{A} of 1,000 or more is a value that makes it possible to suppress low viscosity of epoxy resin due to heating, and to perform high-precision coating and pattern formation.

(8) Haze (Haze Value)

With respect to a cured object obtained by curing the epoxy resin composition to have a thickness of 3 mm, the haze of the cured object at 23° C. was measured using a haze meter (made by Murakami Color Research Laboratory Co., Ltd., trade name: “HR-100”), and the transparency of the cured object was evaluated based on the following standard:

◯: Haze is 3.0% or less,

Δ: Haze is more than 3.0% and not more than 10.0%,

x: Haze is more than 10.0%.

(9) Transmittance

With respect to the cured object obtained by curing the epoxy resin composition to have a thickness of 3 mm, the transmittances at 600 nm, 450 nm and 400 nm, respectively, were measured using a UV-Vis spectrophotometer (made by JASCO Corporation, trade name: “V-630”).

(10) Light Resistance

With respect to the cured object obtained by curing the epoxy resin composition to have a thickness of 3 mm, a light resistance test was conducted using a Dewpanel light control weather meter (made by Suga Test Instruments Co., Ltd., trade name: “DPWL-5”). 96-hour continuous irradiation was performed at a test temperature of 60° C. The YI after the light resistance test was measured, and the light resistance of the cured object was evaluated with the following standard. Further, the measurement of the YI value was conducted using a spectroscopic color difference meter (made by Nippon Denshoku Industries Co., Ltd., “SE-2000”) in a transmission mode.

◯: YI after the light resistance test is 10.0% or less.

x: YI after the light resistance test exceeds 10.0%.

### Production Example 1

### Production of Vinyl Polymer Particle (B-1)

78.00 mass parts of ion-exchanged water, 2.83 mass parts of methyl methacrylate and 2.17 mass parts of n-butyl methacrylate were put into a separable flask including a maxblend mixer, a reflux cooling pipe, a temperature control apparatus, a drop pump and a nitrogen introduction pipe. The resultant was stirred at 120 rpm while being subjected to bubbling with nitrogen gas for 30 minutes.

Next, the temperature of the liquid in the separable flask was raised to 80° C. in a nitrogen atmosphere, and then a previously prepared aqueous solution of 0.04 mass part of ammonium persulfate and 2.00 mass parts of ion-exchanged water was put at once in the separable flask and the resultant maintained for 60 minutes to form seed particles.

A mixture obtained by performing emulsification of 86.00 mass parts of methyl methacrylate, 5.50 mass parts of n-butyl methacrylate, 1.50 mass parts of n-butyl acrylate, 2.00 mass parts of methacrylic acid, 1.00 mass part of an emulsifier (ammonium di-2-ethylhexylsulfosuccinate) and 50.00 mass parts of ion-exchanged water using a homogenizer (made by IKA Japan K.K., trade name: “Ultra-Turrax T-25”, 25,000 rpm) was dripped into the flask containing the above seed particle in 300 min, and the resultant was maintained for 1 hour to complete polymerization and obtain a vinyl polymer latex. The result of the evaluation of the particle diameter of the vinyl polymer particle in the obtained vinyl polymer latex is shown in Table 1.

The obtained vinyl polymer latex was subjected to spray drying using an L-8 type spray dryer made by Ohkawara Kakohki Co., Ltd. under the following conditions to obtain a vinyl polymer particle (B-1). The result of evaluation of the acetone soluble part of the obtained vinyl polymer particle (B-1), the Mw and Mn of the acetone soluble part, and the content of alkali metal ions are shown in Table 1.

[Spray Drying Conditions]
Type of spraying: rotating disk type
Disk rotation speed: 25,000 rpm
Temperature of hot wind: Inlet temperature: 145° C.; Outlet temperature: 65° C.

TABLE 1

| | | | | Production | Production | Production | Production | Production | Production | Production |
|---|---|---|---|---|---|---|---|---|---|---|
| | | | | Example 1 | Example 2 | Example 3 | Example 4 | Example 5 | Example 6 | Example 7 |
| Type of vinyl polymer particle | | | | B-1 | B-2 | B-3 | B-4 | B-5 | B-6 | B′-1 |
| 1^{st} stage | Seed particle | Ion-exchanged | | 78.00 | 78.00 | 78.00 | 78.00 | 78.00 | 78.00 | 78.00 |
| polymerization | (mass part) | water | | | | | | | | |
| | | Monomer | MMA | 2.83 | 2.83 | 2.83 | 2.83 | 2.83 | 2.83 | 2.83 |
| | | mixture | n-BMA | 2.17 | 2.17 | 2.17 | 2.17 | 2.17 | 2.17 | 2.17 |
| | | Ammonium | | 0.04 | 0.04 | 0.04 | 0.04 | 0.04 | 0.04 | 0.02 |
| | | persulfate | | | | | | | | |
| | | Ion-exchanged | | 2.00 | 2.00 | 2.00 | 2.00 | 2.00 | 2.00 | 2.00 |
| | | water | | | | | | | | |
| | Constitution of | Monomer | MMA | 86.00 | 84.00 | 81.20 | 78.00 | 82.20 | 53.50 | 85.94 |
| | dripping | mixture | n-BMA | 5.50 | 5.50 | 5.50 | 5.50 | 5.50 | 8.00 | 5.00 |
| | polymerization | | n-BA | 1.50 | 1.50 | 1.50 | 1.50 | 1.50 | 1.00 | |
| | (mass part) | | MAA | 2.00 | 4.00 | 6.80 | 10.00 | | 2.50 | 4.00 |
| | | | HEMA | | | | | 5.80 | | |
| | | | AMA | | | | | | | 0.06 |

| | | | | | | | |
|---|---|---|---|---|---|---|---|
| Emulsifier | 1.00 | 1.00 | 1.00 | 1.00 | 1.00 | 0.70 | 1.00 |
| V-65 | | | | | | | 0.02 |
| Ion-exchanged | 50.00 | 50.00 | 50.00 | 50.00 | 50.00 | 35.00 | 50.00 |
| water | | | | | | | |

| | | | | | | | |
|---|---|---|---|---|---|---|---|
| Dripping time (min) | 300 | 300 | 300 | 300 | 300 | 210 | 300 |

| | | | | |
|---|---|---|---|---|
| 2^{nd} stage | Constitution of | Monomer | MMA | 23.70 |
| polymerization | dripping | mixture | n-BMA | 2.20 |
| | polymerization | | n-BA | 0.25 |
| | (mass part) | | MAA | 3.85 |

| | |
|---|---|
| Emulsifier | 0.30 |
| Ion-exchanged | 15.00 |
| water | |

| | Dripping time (min) | | | | | | 90 | |
|---|---|---|---|---|---|---|---|---|
| Emulsion | Volume average (Dv) (nm) | 605 | 600 | 592 | 605 | 595 | 604 | 596 |
| particle | Number average (Dn) (nm) | 555 | 552 | 542 | 555 | 547 | 554 | 549 |
| diameter | Monodispersity (Dv/Dn) | 1.09 | 1.09 | 1.09 | 1.09 | 1.09 | 1.09 | 1.09 |
| Acetone soluble part (%) | | >98 | >98 | >98 | >98 | >98 | >98 | 10 |
| Molecular | Mw | 81 | 82 | 87 | 85 | 79 | 78 | 45 |
| weight of | Mn | 31 | 29 | 33 | 34 | 29 | 26 | 19 |
| acetone | | | | | | | | |
| soluble part | | | | | | | | |
| (ten thousand) | | | | | | | | |

| | | | | | | | |
|---|---|---|---|---|---|---|---|
| Content of alkali metal ions (ppm) | <1 | <1 | <1 | <1 | <1 | <1 | <1 |

The abbreviations in the table indicate the following compounds.

MMA: methyl methacrylate (produced by Mitsubishi Rayon Co., Ltd., trade name: “Acryester M”)

n-BMA: n-butyl methacrylate (produced by Mitsubishi Rayon Co., Ltd., trade name: “Acryester B”)

n-BA: n-butyl acrylate (produced by Mitsubishi Chemical Corporation)

MAA: methacrylic acid (produced by Mitsubishi Rayon Co., Ltd., trade name: “Acryester MAA”)

HEMA: 2-hydroxyethyl methacrylate (produced by Mitsubishi Rayon Co., Ltd., trade name: “Acryester HO”)

AMA: allyl methacrylate (produced by Mitsubishi Rayon Co., Ltd., trade name: “Acryester A”)

Emulsifier: ammonium di-2-ethylhexylsulfosuccinate (produced by TOHO Chemical Industry Co., Ltd., trade name: “Rikacol M-300”)

V-65: 2,2′-azobis(2,4-dimethylvaleronitrile) (produced by Wako Pure Chemical Industries, Ltd., trade name: “V-65”, 10 hour half-life temperature: 51° C.)

### Production Examples 2 to 5 and Production Example 7

### Productions of Vinyl Polymer Particles (B-2) to (B-5) and of Vinyl Polymer Particle (B′-1)

The materials of the compositions in the first stage as shown in Table 1 were used as raw materials for obtaining the polymer articles. Except for the above, vinyl polymer particles (B-2) to (B-5) and a vinyl polymer particle (B′-1) were obtained in the same manner as in Production Example 1. The result of the evaluation is shown in Table 1.

### Production Example 6

### Manufacture of Vinyl Polymer Particle (B-6)

78.00 mass parts of ion-exchanged water, 2.83 mass parts of methyl methacrylate and 2.17 mass parts of n-butyl methacrylate were put into the separable flask including a maxblend mixer, a reflux cooling pipe, a temperature control apparatus, a drop pump and a nitrogen introduction pipe. The resultant was stirred at 120 rpm while being subjected to bubbling with nitrogen gas for 30 minutes.

Next, the temperature of the liquid in the separable flask was raised to 80° C. in a N₂-atmosphere, and then the previously prepared aqueous solution of 0.04 mass part of ammonium persulfate and 2.00 mass parts of ion-exchanged water was put at once into the separable flask and the resultant was maintained for 60 min to form seed particles.

A mixture obtained by performing emulsification of 53.50 mass parts of methyl methacrylate, 8.00 mass parts of n-butyl methacrylate, 1.00 mass part of n-butyl acrylate, 2.50 mass parts of methacrylic acid, 0.70 mass part of an emulsifier (ammonium di-2-ethylhexylsulfosuccinate) and 35.00 mass parts of ion-exchanged water using the homogenizer (made by IKA Japan K.K., trade name: “Ultra-Turrax T-25”, 25,000 rpm) was dripped into the flask containing the above seed particles for 210 minutes, and the resultant was maintained for 1 hour to complete the first stage polymerization, thereby obtaining a first-stage polymerization liquid.

Moreover, a mixture for the second stage polymerization, which was obtained by performing emulsification of 23.70 mass parts of methyl methacrylate, 2.20 mass parts of n-butyl methacrylate, 0.25 mass part of n-butyl acrylate, 3.85 mass parts of methacrylic acid, 0.30 mass part of an emulsifier (ammonium di-2-ethylhexylsulfosuccinate) and 15.00 mass parts of ion-exchanged water using the homogenizer (made by IKA Japan K.K., trade name: “Ultra-Turrax T-25”, 25,000 rpm), was dripped into the first-stage polymerization liquid for 90 minutes, and the resultant was maintained for 1 hour to complete polymerization, thereby obtaining a vinyl polymer latex. The result of evaluation of the particle diameter of the vinyl polymer particle in the obtained vinyl polymer latex is shown in Table 1.

The obtained vinyl polymer latex was subjected to spray drying as in the case of Production Example 1 to obtain a vinyl polymer particle (B-6). The evaluation result of the acetone soluble part of the obtained vinyl polymer particle (B-6), the Mw and Mn of the acetone soluble part, and the content of alkali metal ions are shown in Table 1.

### Example 1

100 mass parts of bisphenol A-type alicyclic epoxy resin (produced by Mitsubishi Chemical Corporation, trade name: “YX-8000”) and 10 mass parts of the vinyl polymer particle (B-1) were weighted and then mixed at a rotation speed of 1,200 rpm for 3 min under atmospheric pressure using the planetary vacuum mixer (made by THINKY, trade name: “Awatori Rentaro ARV-310LED”) to obtain a mixture.

A three-roll mill (made by EXAKT, “M-80E”) was used. The obtained mixture was treated by passing through the three-roll mill, at a roll rotation speed of 200 rpm, once at roll intervals of 20 μm and 10 μm, once at roll intervals of 10 μm and 5 μm, and once roll intervals of 5 μm and 5 μm.

Moreover, the obtained mixture was again mixed and defoamed at a rotation speed of 1,200 rpm for 2 min under a reduced pressure of 3 KPa using the planetary vacuum mixer (made by THINKY, trade name: “Awatori Rentaro ARV-310LED”) to obtain an epoxy resin composition.

The dispersibility of the vinyl polymer particle in the obtained epoxy resin composition and the gelation properties of the epoxy resin composition were evaluated. The result obtained is shown in Table 2.

### Example 10

Next, to the above epoxy resin composition, 77 mass parts of 4-methylhexahydrophthalic anhydride (produced by New Japan Chemical Co., Ltd., trade name: “Rikacid MH-700”) as a curing agent, and 1 mass part of tetrabutylphosphonium diethylphosphodithionate (produced by Nippon Chemical Industrial Co., Ltd., trade name: “Hishicolin PX-4ET”) as a curing accelerator were added. The resultant was again mixed and defoamed at a rotation speed of 1,200 rpm for 2 min under a reduced pressure of 3 KPa using the planetary vacuum mixer (made by THINKY, trade name: “Awatori Rentaro ARV-310LED”) to obtain an epoxy resin composition containing a curing agent and a curing accelerator.

A mold was made by two tempered glass plates having a length of 300 mm, a width of 300 mm and a thickness of 5 mm, wherein a polyethylene terephthalate (PET) film (produced by Toyobo Co., Ltd., trade name: TN200) was attached to a surface of each of the plates, the tempered glass plates were disposed opposite with the surfaces having the PET films thereon face-to-face, and a Teflon (registered trademark) spacer sheet having a thickness of 3 mm was sandwiched between the tempered glass plates.

Next, the above epoxy resin composition containing a curing agent and a curing accelerator was flowed into the mold and was fixed by a holder, followed by being pre-cured at 100° C. for 3 hours, then cured at 120° C. for 4 hours, and then removed from the mold to form a cured object having a thickness of 3 mm.

A test piece having a length of 30 mm, a width of 30 mm and a thickness of 3 mm was cut from the obtained cured object, and an evaluation was performed for its haze, transmittance and light resistance. The result obtained is shown in Table 3.

TABLE 2

| | | | Example 1 | Example 2 | Example 3 | Example 4 | Example 5 | Example 6 | Example 7 |
|---|---|---|---|---|---|---|---|---|---|
| Mixing | Epoxy | YX-8000 | 100 | 100 | 100 | 100 | 100 | 100 | |
| (mass part) | resin (A) | Cel2021P | | | | | | | 100 |
| | Vinyl | B-1 | 10 | | | | | | |
| | polymer | B-2 | | 10 | | | | | 10 |
| | particle | B-3 | | | 10 | | | | |
| | (B) | B-4 | | | | 10 | | | |
| | | B-5 | | | | | 10 | | |
| | | B-6 | | | | | | 10 | |
| | | B′-1 | | | | | | | |
| Evaluation | Dispersibility | | ◯ | ◯ | ◯ | ◯ | ◯ | ◯ | ◯ |
| of epoxy | Evaluation | Gelation | 93 | 101 | 104 | 110 | 96 | 106 | 73 |
| resin | of gelation | temperature | | | | | | | |
| composition | properties | (° C.) | | | | | | | |
| | | Gelation | ◯ | ◯ | ◯ | ◯ | ◯ | ◯ | ◯ |
| | | performance | | | | | | | |

| | | | | | Comparative | Comparative | Comparative |
|---|---|---|---|---|---|---|---|
| | | | Example 8 | Example 9 | Example 1 | Example 2 | Example 3 |
| Mixing | Epoxy | YX-8000 | | | 100 | 100 | |
| (mass part) | resin (A) | Cel2021P | 100 | 100 | | | 100 |
| | Vinyl | B-1 | | | | | |
| | polymer | B-2 | | | | | |
| | particle | B-3 | | | | | |
| | (B) | B-4 | 10 | | | | |
| | | B-5 | | 10 | | | |
| | | B-6 | | | | | |
| | | B′-1 | | | 10 | | |
| Evaluation | Dispersibility | | ◯ | ◯ | ◯ | — | — |
| of epoxy | Evaluation | Gelation | 83 | 71 | 104 | No gelation | No gelation |
| resin | of gelation | temperature | | | | | |
| composition | properties | (° C.) | | | | | |
| | | Gelation | ◯ | ◯ | Δ | — | — |
| | | performance | | | | | |

TABLE 3

| | | | Exam- | Exam- | Exam- | Exam- | Exam- | Exam- | Exam- | Exam- | Exam- | Comparative |
|---|---|---|---|---|---|---|---|---|---|---|---|---|
| | | | Ple 10 | Ple 11 | Ple 12 | Ple 13 | Ple 14 | Ple 15 | Ple 16 | Ple 17 | Ple 18 | Example 4 |
| Mixing | Epoxy resin (A) | YX-8000 | 100 | 100 | 100 | 100 | 100 | 100 | | | | 100 |
| (part) | | Cel2021P | | | | | | | 100 | 100 | 100 | |
| | | JER828 | | | | | | | | | | |
| | Vinyl polymer | Type | B-1 | B-2 | B-3 | B-4 | B-5 | B-6 | B-2 | B-4 | B-5 | B′-1 |
| | particle (B) | Amount | 10 | 10 | 10 | 10 | 10 | 10 | 10 | 10 | 10 | 10 |
| | Curing agent | MH-700 | 77 | 77 | 77 | 77 | 77 | 77 | 117 | 117 | 117 | 77 |
| | Curing | PX-4ET | 1 | 1 | 1 | 1 | 1 | 1 | 1 | 1 | 1 | 1 |
| | accelerator | | | | | | | | | | | |
| Evaluation | Haze (23° C.) | | Δ | ◯ | ◯ | ◯ | ◯ | ◯ | ◯ | ◯ | ◯ | X |
| of epoxy | Transmittance | 400 nm | 57 | 88 | 90 | 91 | 85 | 89 | 83 | 85 | 84 | 26 |
| resin cured | (%) | 450 nm | 64 | 90 | 91 | 91 | 87 | 90 | 86 | 88 | 88 | 35 |
| object | | 600 nm | 77 | 91 | 92 | 92 | 90 | 90 | 90 | 91 | 91 | 56 |
| | Light resistance | YI | 9.1 | 8.8 | 8.2 | 8.4 | 9.5 | 8.4 | 8.1 | 7.5 | 7.3 | |
| | | Determination | ◯ | ◯ | ◯ | ◯ | ◯ | ◯ | ◯ | ◯ | ◯ | |

### Examples 2 to 6, Examples 11 to 15 and Comparative Examples 1 and 4

Except that the vinyl polymer particles (B-2) to (B-6) and the vinyl polymer particle (B′-1) shown in Table 2 and Table 3 were used, epoxy resin compositions and cured objects were obtained in the same manner as in Examples 1 and 10. The results of the evaluations with respect to the obtained epoxy resin compositions and cured objects are shown in Table 2 and Table 3.

### Comparative Examples 2 and 5

Except that the vinyl polymer particle (B) was not used, epoxy resin compositions and cured objects were obtained in the same manner as in Examples 1 and 10. The results of the evaluations with respect to the obtained epoxy resin compositions and cured objects are shown in Table 2 and Table 3.

### Examples 7 to 9 and Examples 16 to 18

100 mass parts of “Celloxide2021” (trade name) produced by Daicel Chemical Industries, Ltd. were used as the alicyclic epoxy resin (A), and the vinyl polymer particles shown in Table 2 were used. Except for the above, as in the case of Example 1, the results of the evaluations for the epoxy resin compositions are shown in Table 2.

Next, the curing agent and the curing accelerator were mixed in the above epoxy resin composition in the mixing amounts shown in Table 3. Except for the above, a cured object was made in the same way of Example 10, and the haze, transmittance and light resistance thereof were evaluated. The result obtained is shown in Table 3.

### Comparative Examples 3 and 6

Except that the vinyl polymer particle (B) was not used, epoxy resin compositions and cured objects were obtained in the same manner as in Examples 7 and 16. The results of the evaluations with respect to the obtained epoxy resin compositions and cured objects are shown in Table 2 and Table 3.

### Comparative Example 7

Bisphenol A-type alicyclic epoxy resin (produced by Japan Epoxy Resins Co. Ltd., “Epikote828” (trade name)) was used instead of the alicyclic epoxy resin (A), and the vinyl polymer particle (B-2) was used. Except for the above, an epoxy resin composition was obtained in the same manner as in Example 1. Next, the curing agent and the curing accelerator were mixed in the above epoxy resin composition in the mixing amounts shown in Table 3. Except for the above, a cured object was manufactured in the same manner as in Example 10, and the haze, transmittance and light resistance thereof were evaluated. The result obtained is shown in Table 3.

As clearly shown in Table 2, the vinyl polymer particle of the epoxy resin composition of the invention obtained by mixing the vinyl polymer particles (B-1) to (B-6) used in the invention has excellent dispersibility and high gelation properties. In addition, the cured object of the invention obtained by curing the epoxy resin composition of the invention has high transparency and light resistance.

For example, when the cured object of the epoxy resin is used as an optical semiconductor material, the haze of the epoxy resin cured object having a thickness of 3 mm is preferably 3.0% or less, and the transmittance of the epoxy resin cured object having a thickness of 3 mm is preferably 50.0% or higher. Moreover, an epoxy resin cured object still having less coloration even after the light resistance test is preferred, and the YI value of the epoxy resin cured object of 3 mm thick after the light resistance test is preferably 10.0% or less.

Meanwhile, it is clear from Comparative Examples 1 and 4 that the gelation properties of the epoxy resin composition obtained by mixing the vinyl polymer particle having less than 30 mass % of the acetone soluble part were low, and the haze and transmittance of the cured object were also poor. In regard to the YI value of Comparative Example 4 after the light resistance test, since the cured object was not transparent, the measurement could not be conducted using the present measurement method (transmission mode).

Moreover, in the cases of Comparative Examples 2 and 3 where the vinyl polymer particle was not added to the epoxy resin, the epoxy resin did not gelate. In addition, it is clear from Comparative Examples 5 and 6 that the light resistance of the cured object was low.

In addition, in Comparative Example 7 where bisphenol A-type alicyclic epoxy resin was used instead of the alicyclic epoxy resin (A), the light resistance of the cured object was low,

What is claimed is:

1. An epoxy resin composition comprising an alicyclic epoxy resin (A) and a vinyl polymer particle (B), wherein an acetone soluble part of the vinyl polymer particle (B) is 30 mass % or more, a mass average molecular weight of the acetone soluble part is 100,000 or more, and a volume average primary particle diameter (Dv) of the vinyl polymer particle (B) is 200 nm or more.

2. The epoxy resin composition of claim 1, wherein the alicyclic epoxy resin (A) is selected from at least one of 3,4-epoxycyclohexylmethyl 3′,4′-epoxycyclohexanecarboxylate and bisphenol A-type hydrogenated alicyclic epoxy resin.

3. The epoxy resin composition of claim 1, wherein the vinyl polymer particle (B) is obtained by polymerizing a monomer material, and the monomer material comprises 1 mass % or more of at least one monomer containing a functional group that is selected from a vinyl monomer containing a carboxyl group and a vinyl monomer containing a hydroxyl group.

4. The epoxy resin composition of claim 3, wherein the monomer material comprises 3 mass % or more of the monomer containing a functional group.

5. The epoxy resin composition of claim 1, wherein the vinyl polymer particle (B) is a pregel agent for epoxy resin.

6. The epoxy resin composition of claim 1, wherein a cured object obtained by curing the epoxy resin composition and having a thickness of 3 mm has a total light transmittance of 50.0% or higher under 400 nm at 23° C.

7. The epoxy resin composition of claim 6, wherein the total light transmittance is 80.0% or higher.

8. The epoxy resin composition of claim 1, wherein a cured object obtained by curing the epoxy resin composition and having a thickness of 3 mm has a YI value of 10.0 or less after being subjected to a light resistance test under 96-hour continuous irradiation at a test temperature of 60° C. using a Dewpanel light control weather meter.

9. A cured object obtained by curing the epoxy resin composition of claim 1.

10. An optical semiconductor sealing material using the epoxy resin composition of claim 1.

11. A pregel agent for alicyclic epoxy resin, comprising a vinyl polymer particle (B), wherein an acetone soluble part of the vinyl polymer particle (B) is 30 mass % or more, a mass average molecular weight of the acetone soluble part is 100,000 or more, and a volume average primary particle diameter (Dv) of the vinyl polymer particle (B) is 200 nm or more.
